(19) United States
(12) Patent Application Publication
(10) Pub. No.: US 2014/0131726 A1
(43) Pub. Date: May 15, 2014

(54) SEMICONDUCTOR LIGHT EMITTING DEVICE AND METHOD OF MANUFACTURING THE SAME

(71) Applicant: Samsung Electronics Co., Ltd., Suwon-si (KR)

(72) Inventors: Sang Don LEE, Suwon (KR); Jong Uk SEO, Suwon (KR); Sang Heon HAN, Suwon (KR)

(73) Assignee: SAMSUNG ELECTRONICS CO., LTD., Suwon-si (KR)

(21) Appl. No.: 13/974,751

(22) Filed: Aug. 23, 2013

(30) Foreign Application Priority Data
Nov. 14, 2012 (KR) 10-2012-0128928

(51) Int. Cl. H01L 33/32; H01L 33/00

(52) U.S. Cl. CPC H01L 33/32; H01L 33/0075
USPC 257/76; 438/47

(57) ABSTRACT

There are provided a semiconductor light emitting device and a method of manufacturing the same. The semiconductor light emitting device includes a base layer configured of a group III nitride semiconductor, a polarity modifying layer formed on a group III element polar surface of the base layer, and a light emitting laminate having a multilayer structure of the group III nitride semiconductor formed on the polarity modifying layer, an upper surface of at least one layer in the multilayer structure being formed of an N polar surface.

### CROSS-REFERENCE TO RELATED APPLICATIONS

This application claims the priority to, and the benefit of, Korean Patent Application No. 10-2012-0128928 filed on Nov. 14, 2012, with the Korean Intellectual Property Office, the disclosure of which is incorporated herein by reference.

### TECHNICAL FIELD

The present disclosure relates to a light emitting device and a method of manufacturing the same.

### BACKGROUND

A light emitting diode (LED) is a semiconductor light emitting device capable of generating various colors of light through the recombination of electrons and holes at a junction between p-type and n-type semiconductors when a current is applied thereto. Compared to light emitting devices based on filaments, such semiconductor light emitting devices have favorable characteristics such as a relatively long lifespan, low power consumption, excellent initial operating characteristics, and the like. Hence, demand for semiconductor light emitting devices is continuously increasing. In particular, a group III nitride semiconductor capable of emitting light having a blue-series short-wavelength region has recently come to prominence.

Subsequently to light emitting diodes using such a nitride semiconductor being developed, many technical developments have been carried out in order to increase a range of practical uses thereof, such that research into light sources for general illumination devices and field lighting devices has been actively undertaken. Particularly, nitride light emitting devices, according to the related art, have mainly been used as components applied to low input—high output mobile products, and recently, the range of practical uses thereof has been being expanded to high current—high output fields.

In the case of an LED configured from a nitride semiconductor, a surface (e.g., an upper surface) of a semiconductor epitaxy layer (e.g., a GaN layer) is provided as a Ga-polar type surface finished by Ga. In the case in which an LED structure is grown on the Ga-polar surface described above, an InGaN active layer and a P—GaN layer have a conduction band offset of 0.43 eV. However, 0.43 eV is not a sufficient magnitude to prevent the occurrence of an electron leakage current. Therefore, the case in which a leakage current is generated due to overflowing of electrons while an LED device is operated. This may deteriorate light emission efficiency.

In addition, in the case of an LED formed on the Ga-polar surface, an energy barrier (e.g., for electrons) of approximately 0.34 eV is formed at an interface of the N—GaN layer and the active layer due to a piezoelectric field, and similarly, an energy barrier (e.g., for holes) having a predetermined magnitude is also formed at an interface of the P—GaN layer and the active layer. Since the barriers described above interfere with a smooth injection of electrons and holes, an LED operating voltage may be problematically increased.

Accordingly, a need exists for a semiconductor light emitting device having excellent internal quantum efficiency for improved light emission efficiency. A need also exists for a method of manufacturing such a semiconductor light emitting device.

### SUMMARY

An aspect of the present disclosure relates to a light emitting device capable of having improved light emission efficiency by allowing electrons and holes to be injected into an active layer more effectively.

Another aspect of the present disclosure relates to a method of effectively manufacturing such a light emitting device.

An aspect of the present disclosure relates to a semiconductor light emitting device including: a base layer configured of a group III nitride semiconductor; a polarity modifying layer formed on a group III element polar surface of the base layer; and a light emitting laminate having a multilayer structure of the group III nitride semiconductor formed on the polarity modifying layer, an upper surface of at least one layer in the multilayer structure being formed as an N polar surface.

The base layer may be formed of AlN.

An upper surface of the base layer may be formed as an Al polar surface.

The polarity modifying layer may be formed of an oxide of a material forming the base layer.

The polarity modifying layer may be formed of an Al oxide.

The polarity modifying layer may be formed of a nitride of the material forming the base layer.

The light emitting laminate may include a first conductive semiconductor layer, an active layer and a second conductive semiconductor layer, respectively formed of a group III nitride semiconductor.

The first conductive semiconductor layer, the active layer and the second conductive semiconductor layer may be sequentially disposed on the polarity modifying layer.

In the light emitting laminate, at least an upper surface of the first conductive semiconductor layer may be formed of an N polar surface.

Respective upper surfaces of the first conductive semiconductor layer, the active layer and the second conductive semiconductor layer may be formed of the N polar surface.

The base layer may be formed on a substrate formed of a material different from that of the base layer.

The substrate may be formed of sapphire and a surface of the substrate directed toward the base layer may be an Al polar surface.

The base layer may be formed of AlN, and the base layer and the substrate may not have a different base layer formed of GaN therebetween.

The base layer may have a thickness of 20 to 200 nm.

The polarity modifying layer may have a thickness of 0.3 to 10 nm.

According to another aspect of the present disclosure, there is provided a semiconductor light emitting device including: a substrate; a base layer formed on the substrate, the base layer being formed of AlN and having an Al polar upper surface; a polarity modifying layer formed on the Al polar upper surface and formed of an Al oxide; and a nitride semiconductor layer formed on the polarity modifying layer and having an N polar upper surface.

According to another aspect of the present disclosure, there is provided a method of manufacturing a semiconductor light emitting device, the method including: forming a base layer configured of a group III nitride semiconductor, on a substrate; forming a polarity modifying layer by oxidation or nitride processing at least an upper surface of the base layer; and forming a light emitting laminate including a first conductive semiconductor layer, an active layer and a second conductive semiconductor layer, on the polarity modifying layer.

The forming of the polarity modifying layer may include forming an oxide film having one to ten atomic layers by oxidizing the upper surface of the base layer.

The forming of the polarity modifying layer may be performed under an ozone gas atmosphere.

The forming of the light emitting laminate may include forming an N polar surface on an upper surface of at least one of the first conductive semiconductor layer, the active layer and the second conductive semiconductor layer.

### BRIEF DESCRIPTION OF THE DRAWINGS

The foregoing and other features of the present disclosure will be apparent from more particular description of embodiments of the inventive concept, as illustrated in the accompanying drawings in which like reference characters may refer to the same or similar elements throughout the different views. The drawings are not necessarily to scale, emphasis instead being placed upon illustrating the principles of the embodiments of the inventive concept. In the drawings, the thickness of layers and regions may be exaggerated for clarity.

FIG. 1 is a schematic cross-sectional view of a semiconductor light emitting device according to an embodiment of the present disclosure.

FIGS. 2, 3, 6 and 11 are schematic cross-sectional views illustrating respective processes in a method of manufacturing a semiconductor light emitting device according to an embodiment of the present disclosure.

FIGS. 4 and 5 illustrate atoms in a combined state so as to provide an aspect in which a base layer surface is modified due to an oxidation treatment.

FIGS. 7 and 8 illustrate band gap energy and current density in respective positions inside a Ga polar surface light emitting device and an N polar surface light emitting device.

FIG. 9 is a simulation graph comparing current density based on a voltage in Ga polar surface and N polar surface light emitting devices.

FIG. 10 is a simulation graph comparing internal quantum efficiencies based on current density in Ga polar surface and N polar surface light emitting devices.

FIGS. 12 and 13 are schematic cross-sectional views of a semiconductor light emitting device according to another embodiment of the present disclosure.

FIGS. 14 and 15 illustrate examples in which a semiconductor light emitting device according to an embodiment of the present disclosure is applied to a package;

FIGS. 16 and 17 illustrate examples in which a semiconductor light emitting device according to an embodiment of the present disclosure is applied to a backlight unit.

FIG. 18 illustrates an example in which a semiconductor light emitting device according to an embodiment of the present disclosure is applied to an illumination device.

FIG. 19 illustrates an example in which a semiconductor light emitting device according to an embodiment of the present disclosure is applied to a headlamp.

### DETAILED DESCRIPTION OF THE EMBODIMENTS

Hereinafter, embodiments of the present disclosure will be described in detail with reference to the accompanying drawings. The present disclosure may, however, be embodied in many different forms and should not be construed as being limited to the embodiments set forth herein. Rather, these embodiments are provided so that this disclosure will be thorough and complete, and will fully convey the scope of the inventive concept to those skilled in the art.

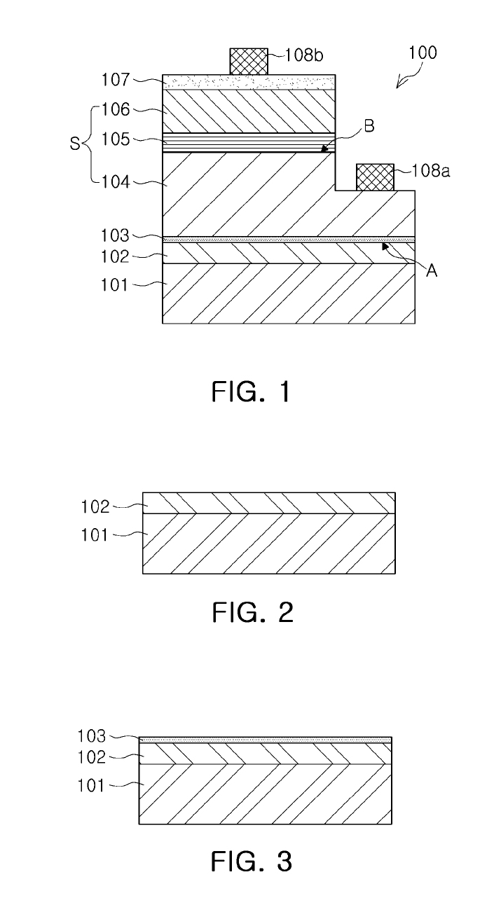

With reference to FIG. 1, a semiconductor light emitting device 100 may include a light emission structure disposed on a substrate 101. That is, the semiconductor light emitting device 100 may include a light emitting laminate S having a first conductive semiconductor layer 104, an active layer 105 and a second conductive semiconductor layer 106, and further, may include a base layer 102 and a polarity modifying layer 103 formed between the substrate 101 and the light emitting laminate S. In addition, the semiconductor light emitting device 100 may include an ohmic electrode layer 107 formed on the second conductive layer 106. First and second electrodes 108a and 108b may be formed on the first conductive semiconductor layer 104 and the ohmic electrode layer 107 respectively. Terms used herein such as ‘upper part’, ‘upper surface’, ‘lower part’, ‘lower surface’, ‘side’, and the like, are based on the drawings, and thus, may be changed in actuality, according to a direction in which a device is disposed.

The substrate 101 may be a semiconductor growth substrate and may be formed using an insulating and conductive semiconductor material such as sapphire, SiC, MgAl₂O₄, MgO, LiAlO₂, LiGaO₂, GaN, or the like. Sapphire, widely used as a material for a nitride semiconductor growth substrate, may be a crystal having Hexa-Rhombo R3c symmetry, may have respective lattice constants of 13.001 Å and 4.758 Å in c-axis and a-axis directions, and may have a C (0001) plane, an A (1120) plane, an R (1102) plane and the like. In this case, since the C plane comparatively facilitates the growth of a nitride thin film and is stable at relatively high temperatures, the C plane may mainly be used as a growth substrate for a nitride semiconductor. As described below, in a case in which a nitride semiconductor, for example GaN, is grown on the substrate 101 such as a sapphire substrate or the like, a surface thereof directed toward the substrate 101 may be an N polar surface. A surface opposite thereto, that is, a GaN upper surface, may be a Ga polar surface. In the present embodiment, the light emitting laminate S may be formed on the N polar surface through the polarity modifying layer 103. Alternatively, as another substrate suitable for use as the substrate 101, a Si substrate may be used. Since the Si substrate is appropriate for obtaining a large diameter and has low manufacturing costs, mass production thereof may be enhanced. When the Si substrate is used, a nucleation layer formed of a material such as AlₓGa₁₋ₓN may be formed on the substrate 101 and a nitride semiconductor having a required structure may be subsequently grown on the nucleation layer.

The base layer 102 formed on the substrate 101 may be formed of a group III nitride semiconductor and may function as a buffer layer such that a crystalline quality of a semiconductor layer grown thereon may be improved. Further, in the present embodiment, in the base layer 102, a surface polarity thereof may be modified to have a more appropriate form for improvements in light emission efficiency through the polarity modifying layer 103 formed on the base layer 102. In detail, in the case of the base layer 102 normally grown on the substrate 101, an upper surface thereof may be formed of a group III element polar surface. This indicates that an outermost portion of the upper surface of the base layer 102 is formed of the group III elements (or the amount thereof present may be more than that of nitrogen). For example, in a case in which the base layer 102 is formed of AlN, the upper surface A of the base layer 102 may become an Al polar surface. When the group III nitride semiconductor is continuously grown on the Al polar surface, an upper surface of the grown semiconductor layer may also be a group III element polar surface. In the case of the group III element polar surface to be described below, suitability for forming a light emitting laminate having excellent light emission efficiency may be deteriorated.

The polarity modifying layer 103 may allow for a change in a surface of the base layer 102 such that an upper surface of the group III nitride semiconductor grown thereon may become an N polar surface. To this end, the polarity modifying layer 103 may be formed by oxidation processing at least an upper surface of the base layer 102. In a case in which the group III nitride semiconductor, for example, a GaN semiconductor, is grown on the polarity modifying layer 103 described above, a Ga atom, rather than N, may first be combined with an O atom, such that a Ga polar surface is formed on a lower part thereof and an N polar surface is formed on an upper surface opposite thereto. In detail, in a case in which the base layer is formed of AlN, the upper surface of the base layer 102 is formed of an oxide film of Al₂O₃ such that the surface thereof is modified. In this case, instead of using AlN, the base layer 102 may be formed of a group III nitride semiconductor, for example, GaN, AlGaN, or the like. However, in an aspect in which Al has ease of oxidation, as compared with other elements, AlN may be used. Therefore, according to an embodiment of the present disclosure, a different base layer formed of GaN may not be present between the base layer 102 and the substrate 101. The principle that the surface of the base layer 102 is modified by oxidation will be described in more detail with regard to the process. On the other hand, in a method of modifying a group III element polar surface of the base layer 102, the N polar surface may also be directly formed by nitride processing the base layer 102 surface, as well as through the oxidation treatment.

In the case in which the light emitting laminate S is formed on the surface modified in the scheme described above, quantum efficiency in the active layer 105 or carrier recombination efficiency may be excellent. Accordingly, driving voltage may be reduced such that the utility of a device may be improved. Describing the light emitting laminate S having a group III nitride semiconductor multilayer structure in more detail, first and second conductive semiconductor layers 104 and 106 may be configured of semiconductors doped with n-type and p-type impurities, respectively. However, the inventive concept is not limited thereto, and the opposite may be the case. That is, first and second conductive semiconductor layers 104 and 106 may be configured of p type and n type semiconductors, respectively. The first and second conductive semiconductor layers 104 and 106 may be formed of a group III nitride semiconductor. For example, a material having the composition represented by an empirical formula AlₓIn_{y}Ga_{1-x-y}N (0≦x≦1, 0≦y≦1, 0≦x+y≦1). The active layer 105 formed between the first and second conductive semiconductor layers 104 and 106 may have a multiple quantum well (MQW) structure in which quantum well layers and quantum barrier layers are alternately stacked on top of each other. For example, a GaN/InGaN structure in the case of a nitride semiconductor. The first and second conductive semiconductor layers 104, 106 and the active layer 105 may be grown by using a process known in the art, such as metal organic chemical vapor deposition (MOCVD), hydride vapor phase epitaxy (HVPE), molecular beam epitaxy (MBE), or the like.

As described above, the upper surface B of the first conductive semiconductor layer 104 formed on the polarity modifying layer 103 may be an N polar surface. Similarly, upper surfaces of the active layer 105 and the second conductive semiconductor layer 106 may also be N polar surfaces. As such, the light emitting laminate based on the N polar surface may have excellent light emission efficiency and require a relatively low operating voltage, such that leakage current is reduced and a carrier restraint effect or the like in the active layer 105 may be improved, as described below.

The ohmic electrode layer 107 may be formed of a material having ohmic characteristics electrically with the second conductive semiconductor layer 106, and may be formed of a transparent conductive oxide such as ITO, CIOC, ZnO, or the like having relatively excellent light transmission properties and ohmic contact characteristics in materials for a transparent electrode. Alternatively, the ohmic contact layer 107 may be formed of a light reflective material, for example, a highly reflective metal. In this case, the semiconductor light emitting device 100 may have a so-called flip chip structure in which the first and second electrodes 108a and 108b are mounted to be directed toward a lead frame or the like of a package. The ohmic electrode layer 107 may be formed using a sputtering method, various deposition methods, or the like. However, the ohmic electrode layer 107 may not necessarily be required in the present embodiment, and may be omitted on a case-by-case basis.

The first and second electrodes 108a and 108b may be formed using a method such as depositing, sputtering, or the like, an electrically conductive material known in the art. For example, at least one of Ag, Al, Ni, Cr, and the like. However, in the case of the structure illustrated in FIG. 1, although the first and second electrodes 108a and 108b are respectively formed on upper surfaces of the first conductive semiconductor layer 104 and the ohmic electrode layer 107, the methods of forming the electrodes 108a and 108b as described above may be provided by way of an example. Thus, an electrode may be formed on various positions of a light emitting laminate, including the first conductive semiconductor layer 104, the active layer 105, and the second conductive semiconductor layer 106.

Hereinafter, with reference to FIGS. 2 to 11, a method of manufacturing a light emitting device having the above-mentioned structure or a structure similar thereto, and an excellent effect in a device manufactured using the method will be described. In particular, an effect obtained by surface modification to an N polar surface will be described in detail below.

First, as illustrated in FIG. 2, the base layer 102 may be formed on the substrate 101. The substrate 101 may be a semiconductor growth substrate formed of the material described above. For example, a sapphire substrate, an Si substrate or the like. The base layer 102 may be configured of a group III nitride semiconductor as described above. For example, the base layer 102 may be formed of a nitride containing Al such as AlN. The base layer 102 may be formed using sputtering equipment, MOCVD equipment, or the like, and may be formed to have a thickness of approximately 20 to 200 nm in consideration of a buffer function or the like.

Subsequently, as illustrated in FIG. 3, the polarity modifying layer 103 may be formed on the base layer 102. As described above, the polarity modifying layer 103 may be obtained by oxidation processing or nitride processing a surface of the base layer 102. For example, in a case in which the base layer 102 is oxidation treated, an oxide film having a thickness of about 0.3 to 10 nm or one to ten atomic layers may be formed by exposing the base layer 102 to ozone (O₃) gas. This is provided in consideration of a range in which the degree of deterioration in electrical characteristics is not relatively great, together with a surface modification effect. Meanwhile, in a case in which the base layer 102 is nitride processed, a scheme in which a heat treatment is performed may be used. For example, at approximately 950° C. for 30 seconds under an N₂ gas atmosphere.

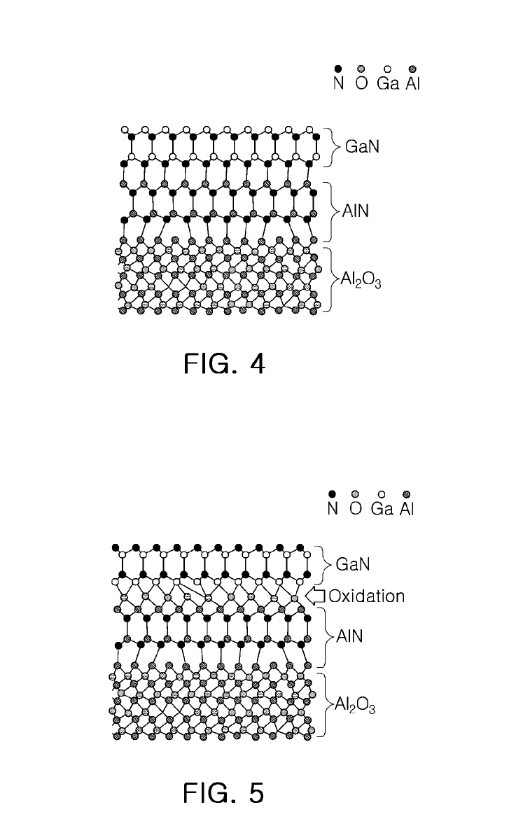

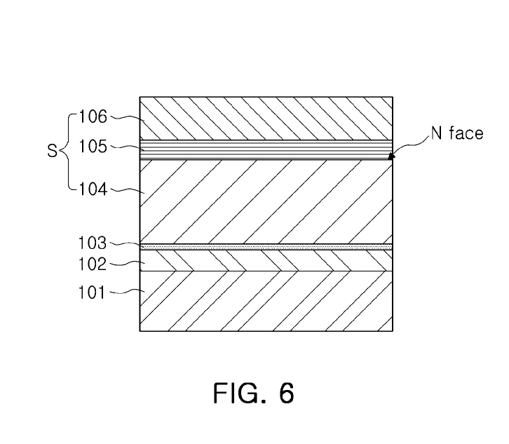

FIGS. 4 and 5 illustrate atoms in a combined state where the surface of the base layer is modified due to an oxidation treatment. FIG. 4 illustrates an example in which the base layer of AlN is formed on the sapphire substrate (Al₂O₃) which a surface of the sapphire substrate directed toward the base layer may be an Al polar surface and GaN is then formed thereon without modifying the surface. Here, an upper surface of the base layer may be an Al polar surface, and in GaN grown thereon, an upper surface thereof may be a Ga polar surface. In the case of FIG. 5, the upper surface of the base layer may be oxidation processed such that an oxide film is formed, and in the case of GaN formed thereon, a lower surface thereof may be a Ga polar surface and an upper surface thereof may be an N polar surface. In the group III nitride semiconductor grown on the N polar surface described above, an upper surface thereof may also be an N polar surface. As illustrated in FIG. 6, the upper surface of the first conductive semiconductor layer 104 grown on the polarity modifying layer 103, that is, a surface directed toward the active layer 105, may be an N polar surface (e.g., N face). Similarly, the upper surface of the active layer 105, that is, a surface directed to the second conductive semiconductor layer 106, may be an N polar surface.

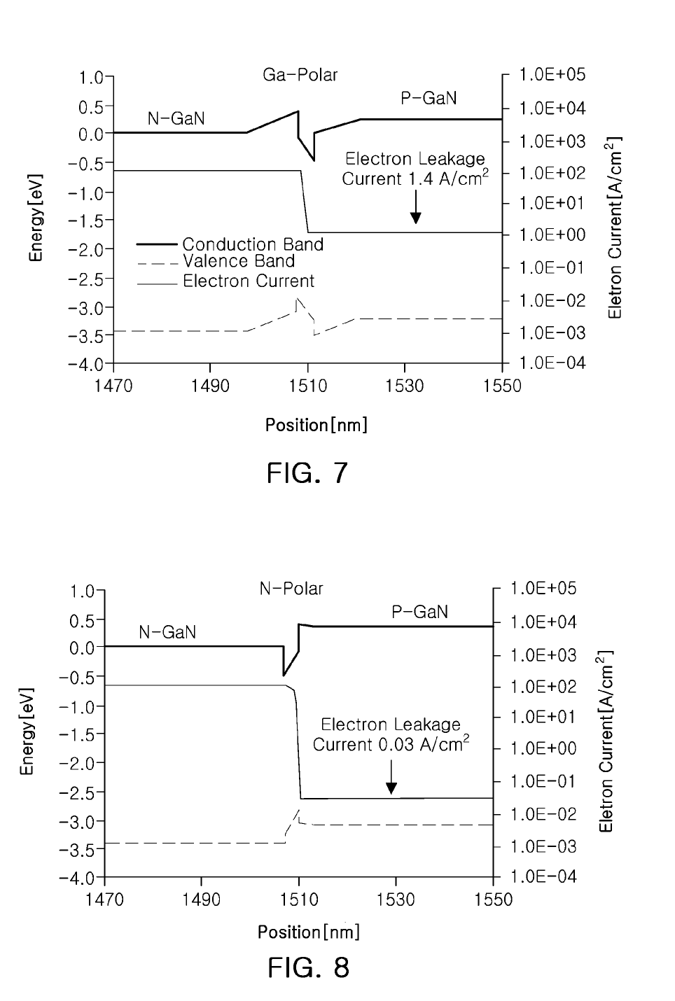

The light emitting device grown on the Ga polar surface and the light emitting device grown on the N polar surface may be compared in terms of performance thereof with reference to FIGS. 7 to 10. FIGS. 7 and 8 illustrate band gap energy and current density in respective positions inside a Ga polar surface light emitting device and an N polar surface light emitting device. Here, although an LED structure in which an InGaN active layer is disposed between N—GaN and P—GaN is used for simplification of simulation, a composition of respective layers may be changed or a different layer may be additionally introduced in an actual structure. As seen in FIG. 7, in the case of the Ga polar surface light emitting device, distortion of band gap energy may occur around the active layer due to a polarization effect. Thus, since a height of a barrier of the second conductive semiconductor layer P—GaN blocking electrons may be relatively low, occurrence of a leakage current may be approximately 1.4 A/cm², a comparatively high extent. In addition, on an interface between the first conductive semiconductor layer (N—GaN) and the active layer, a barrier with respect to electrons may be generated. Similarly, a barrier with respect to holes may be generated on an interface between the second conductive semiconductor layer P—GaN and the active layer such that efficiency in introduction of carriers into the active layer may be lowered.

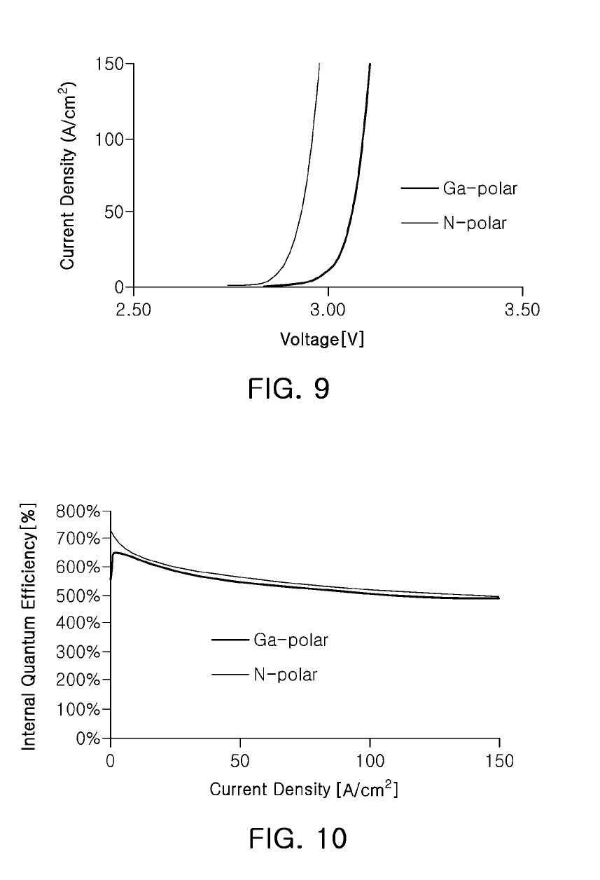

As compared in simulation results of FIG. 8, it can be seen that the second conductive semiconductor layer barrier with respect to electrons may be comparatively great in the N polar surface light emitting device, and the magnitude of leakage current has been significantly reduced to about 0.3 A/cm². In addition, since a barrier interfering with the introduction of carriers into the active layer is barely present, a voltage for obtaining the same current density is also relatively reduced in the N polar surface light emitting device, as illustrated in the graph of FIG. 9 providing current density based on a voltage, thereby lowering a driving voltage required for a device. More specifically, the graph of FIG. 10 illustrates simulation results with regard to internal quantum efficiency based on current density. Here it can be confirmed that the internal quantum efficiency of the N polar surface light emitting device is improved over that of the Ga polar surface light emitting device. As described above, this may be because the amount of electrons and holes injected into the active layer is increased.

As such, in the case of the polarity modifying type light emitting device proposed according to the present embodiment, a light emitting laminate may be grown using the N polar surface. Accordingly, effects such as improved light emission efficiency, reduction of a driving voltage, or the like, may be expected. In particular, polarity may be modified by introducing a based layer and by oxidization processing and nitride processing the base layer, thereby easily obtaining an N polar surface device.

On the other hand, after the light emitting laminate S is formed on the polarity modifying layer 103, operations in which the ohmic electrode layer 107 is formed, such as the light emitting laminate S is appropriately etched and the first and second electrodes 108a and 108b are formed, may be performed, whereby the light emitting device as shown in FIG. 1 may be obtained. Alternatively, the N polar surface light emitting device may be varied as a type other than the type shown in FIG. 1.

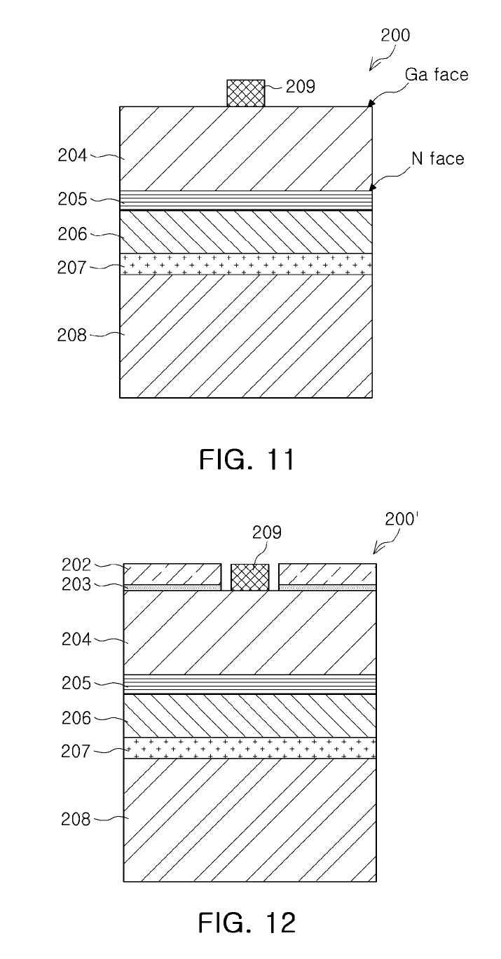

FIGS. 11 to 13 are schematic cross-sectional views of a light emitting device according to another embodiment of the inventive concept.

A semiconductor light emitting device 200 illustrated in FIG. 11 may have a structure in which a reflective metal layer 207 and a light emitting laminate are formed on a conductive substrate 208. The light emitting laminate includes a first conductive semiconductor layer 204, an active layer 205 and a second conductive semiconductor layer 206. This structure is a structure in which the substrate 100, the base layer 102 and the polarity modifying layer 103 provided according to the foregoing embodiment of FIG. 1 are omitted. Also, a first electrode 209 is formed on a group III element polar surface of the first conductive semiconductor layer 204 exposed through the omission described above, for example, a Ga polar surface (e.g., Ga face). In general, since the ohmic characteristic between the first conductive semiconductor layer 204 and the first electrode 209 may be relatively better on the group III element polar surface than on the N polar surface (e.g., N face), electrical characteristics thereof may be improved. The substrate 100, the base layer 102 and the polar modifying layer 103 may be removed by a liftoff process, an etching process, or the like, known in the art.

The reflective metal layer 207 may be formed of a metal capable of providing electrical ohmic characteristics with the second conductive semiconductor layer 206 and having relatively high reflectivity so as to reflect light emitted from the active layer 205. In consideration of the function described above, the reflective metal layer 207 may be formed of a single layer or may have a multilayer structure, including a material such as Ag, Ni, Al, Rh, Pd, Ir, Ru, Mg, Zn, Pt, or Au. In addition, the reflective metal layer 207 may include a barrier layer preventing diffusion of a metallic element.

The conductive substrate 208 may be connected to an external power source such that it may function to apply an electrical signal to the second conductive semiconductor layer 206. In addition, the conductive substrate 208 may serve as a support supporting the light emitting laminate in a process such as a laser liftoff or the like, to remove the substrate used for the growth of the semiconductor, and may be formed of a material including any one of Au, Ni, Al, Cu, W, Si, Se and GaAs. For example, the conductive substrate may be formed using a material doped with Al on an Si substrate. In this case, the conductive substrate 208 may be formed on the reflective metal layer 207 through a process such as a plating method, a sputtering method, a deposition method, or the like. Unlike the description above, the conductive substrate 208 may also be formed by bonding a previously manufactured conductive substrate to the reflective metal layer 207 through the medium of a junction layer formed of a eutectic metal such as AuSn, a conductive polymer, or the like.

FIG. 12 illustrates a semiconductor light emitting device 200′ by way of a variation of the example of FIG. 11. Unlike the foregoing embodiment, the semiconductor light emitting device 200′ may be characterized in that a base layer 202 and a polarity modifying layer 203 may partially remain therein. In this case, as illustrated in FIG. 12, the base layer 202 and the polarity modifying layer 203 having relatively high electrical resistance may be partially removed and the first electrode 209 may then be formed on an exposed portion of the first conductive semiconductor layer 204, instead of directly forming the electrode on the base layer 202 and the polarity modifying layer 203.

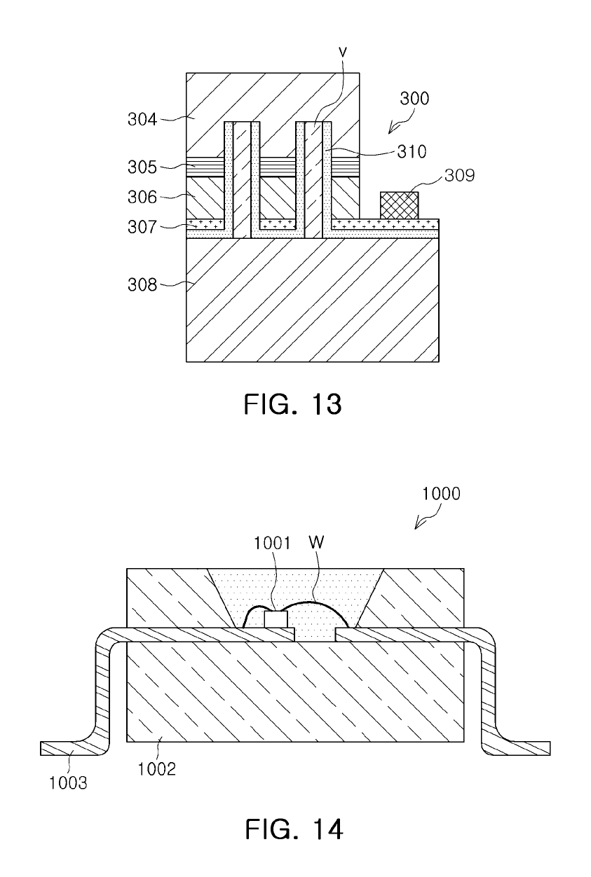

Compared to the embodiment of FIG. 11, a semiconductor light emitting device 300 shown in FIG. 13 may have a difference in terms of a connection scheme of an electrode. In detail, a first conductive semiconductor layer 304 may be electrically connected to a conductive substrate 308 through a conductive via V penetrating an active layer 305, a second conductive semiconductor layer 306, a reflective metal layer 307, and the like. An insulation layer 310 may be interposed around the conductive via V or the like for electrical insulation thereof. In addition, in order to apply an electrical signal to the second conductive semiconductor layer 306, a portion of the light emitting laminate may be removed to expose a portion of a surface of the reflective metal layer 307, and a second electrode 309 may be formed on an exposed portion of the reflective metal layer 307. Here, similarly to the foregoing embodiment, the active layer 305 and the second conductive semiconductor layer 306 are formed on an N polar surface of the first conductive semiconductor layer 304. Since an electrode is not formed on the first conductive semiconductor layer 304, light extraction efficiency may be improved. Also, since current is introduced into the first conductive semiconductor layer 304 through a plurality of conductive vias V, the current may be effectively diffused.

Meanwhile, the light emitting device described above or a light emitting device obtained using the manufacturing method described above may be applied to various fields. That is, the illumination devices as described above may be provided in various package types or may be mounted on a substrate or the like in a package form or as a light emitting device itself to be used as a backlight unit used for a display device such as a liquid crystal display or the like, indoor lighting such as a lamp, a flat illumination device, or the like, or outdoor lighting such as street lighting, signboard lighting, road sign lighting, or the like. In addition, the illumination devices as described above may also be used as various lighting devices for vehicles, for example, automobiles, boats, airplanes or the like. They may also be widely used for electronic appliances such as a television set, a refrigerator or the like, medical appliances, or the like. Hereinafter, a portion of the use examples described above will be described.

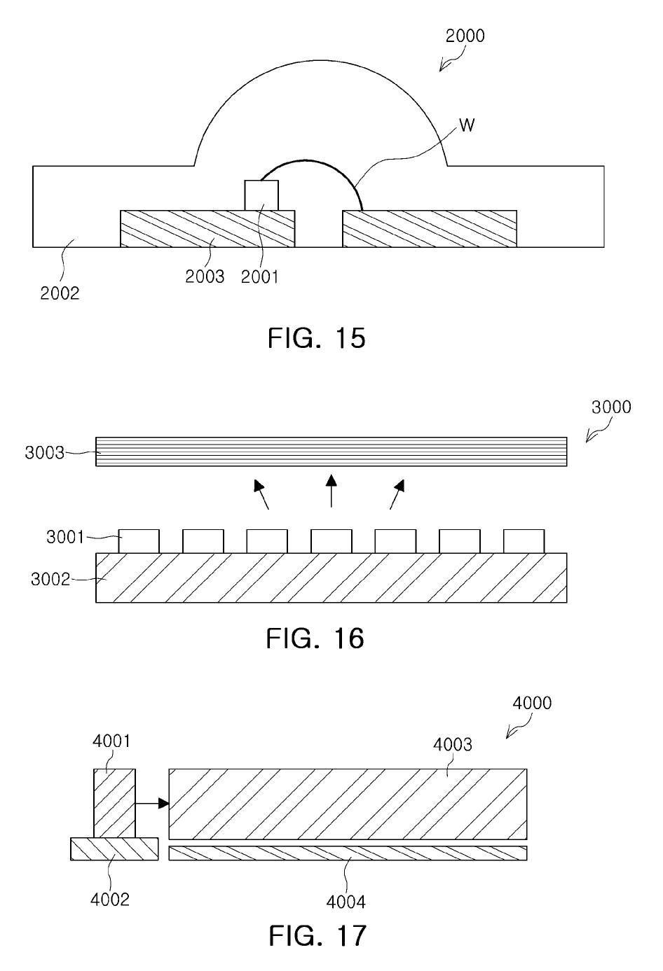

FIGS. 14 and 15 illustrate examples in which a semiconductor light emitting device according to the embodiment of the inventive concept is applied to a package. A package 1000 of FIG. 14 may include a semiconductor light emitting device 1001, a package body 1002 and a single pair of lead frames 1003. The semiconductor light emitting device 1001 may be mounted on the lead frame 1003 so as to be electrically connected to the lead frame 1003 through a wire W. The semiconductor light emitting device 1001 may also be mounted on a different region other than the lead frame 1003. For example, in the package body 1002. The package body 1002 may have a cup shape so as to improve reflective efficiency of light as shown in FIG. 14. This reflective cup may be filled with a light transmission material so as to encapsulate the semiconductor light emitting device 1001, the wire W, and the like. As described above, the semiconductor light emitting device 1001 may have a form in which the light emitting laminate is included using an N polar surface, for example, a structure illustrated in FIG. 1. Unlike the description above, the semiconductor light emitting device 1001 may also have a structure according to another embodiment, and a single wire W may or may not be required according to an electrode type, a mounting scheme, or the like, in the semiconductor light emitting device 1001.

A package 2000 illustrated in FIG. 15 may have a structure similar to that of the foregoing package in that a semiconductor light emitting device 2001 is disposed on a lead frame 2003 and electrical conductivity is formed by a wire W. However package 2000 may have a difference therefrom in that a lower surface of the lead frame 2003 is exposed to the outside so as to be suitable for radiation of light, and a shape of the package 2000 is maintained by a light transmission body 2002 encapsulating the semiconductor light emitting device 2001, the wire W and the lead frame 2003. The semiconductor light emitting device 2001 may have the structure described above, and although FIG. 15 is illustrated based on the form in which a single wire W is used, the number of the wires W may be changed according to an electrode type and a mounting scheme of the semiconductor light emitting device 2001 or the like.

FIGS. 16 and 17 illustrate examples in which a semiconductor light emitting device according to the embodiment of the inventive concept is applied to a backlight unit. With reference to FIG. 16, a backlight unit 3000 may include light sources 3001 formed on a substrate 3002 and at least one optical sheet 3003 disposed above the light sources 3001 mounted on the substrate 3002. The light source 3001 may be provided using alight emitting device package having the structure described above or a structure similar thereto. The light source 3001 may also be provided by directly mounting semiconductor light emitting devices on the substrate 3002, as a so-called chip on board (COB) type light source. Unlike the description with reference to FIG. 16 in which in the backlight unit 3000, the light sources 3001 radiate light toward an upper part in which a liquid crystal display device is disposed; in a backlight unit 4000 according to another embodiment with reference to FIG. 17, a light source 4001 mounted on a substrate 4002 radiates light in a lateral direction, and light radiated as described above may be incident on a light guide plate 4003 such that the incident light may be converted to have the form of a surface light source. Light which has passed through the light guide plate 4003 may be emitted upwardly, and a reflective layer 4004 may be provided on a lower surface of the light guide plate 4003 so as to improve light extraction efficiency.

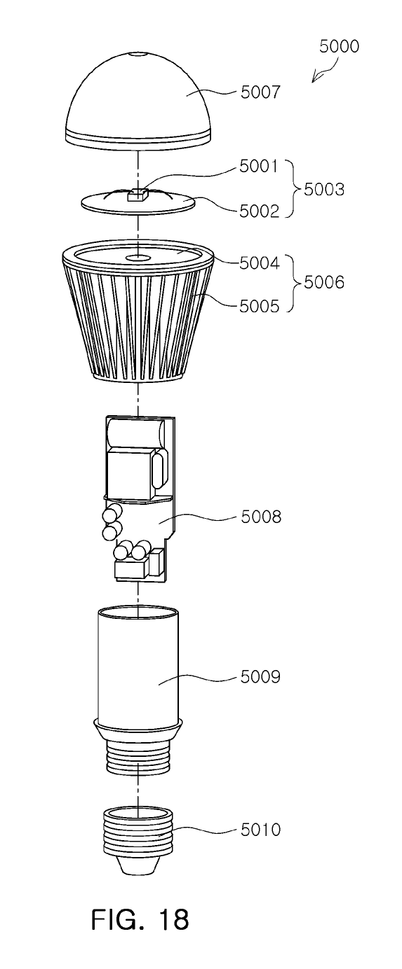

FIG. 18 illustrates an example in which a semiconductor light emitting device according to an embodiment of the inventive concept is applied to an illumination device. With reference to an exploded perspective view of FIG. 18, an illumination device 5000 may be provided as a bulb type lamp by way of example and may include a light emitting module 5003, a driving unit 5008, and an external connection unit 5010. In addition, an external structure such as an external housing 5006, an internal housing 5009 and a cover unit 5007 may be included in the illumination device 5000. The light emitting module 5003 may include the semiconductor light emitting device 5001 described above and a circuit board 5002 on which the light emitting device 5001 is mounted. Although the present embodiment provides the case in which a single semiconductor light emitting device 5001 is mounted on the circuit board 5002, a plurality of semiconductor light emitting devices may be mounted as necessary. In addition, the semiconductor light emitting device 5001 may not be directly mounted on the circuit board 5002, but may be mounted after being manufactured in the form of a package.

Further, in the illumination device 5000, the light emitting module 5003 may include the external housing 5006 operating as a heat emitting unit. The external housing 5006 may include a heat emitting plate 5004 directly contacting the light emitting module 5003 and fins 5005 to improve heat radiation efficiency. In addition, the illumination device 5000 may include the cover unit 5007 mounted above the light emitting module 5003 and having a convex lens shape. The driving unit 5008 may be mounted in the internal housing 5009 and may be connected to the external connection unit 5010 having a socket-like structure to receive power from an external power source. Further, the driving unit 5008 may convert power into an appropriate current source capable of driving the semiconductor light emitting device 5001 of the light emitting module 5003 so as to provide the converted power. For example, the driving unit 5008 may be configured of an AC to DC converter, a rectifying circuit component, or the like.

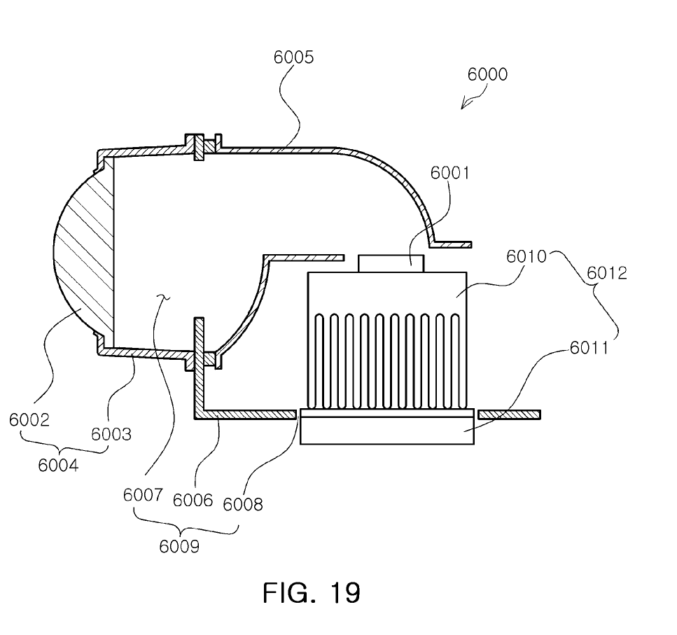

FIG. 19 illustrates an example in which a semiconductor light emitting device according to an embodiment of the inventive concept is applied to a headlamp. With reference to FIG. 19, a headlamp 6000 used for vehicle lighting or the like may include a light source 6001, a reflective unit 6005, and a lens cover unit 6004. The lens cover unit 6004 may include a hollow guide 6003 and a lens 6002. In addition, the headlamp 6000 may further include a heat radiating unit 6012 discharging heat generated by the light source 6001 to the outside. The heat radiating unit 6012 may include a heat sink 6010 and a cooling fan 6011 to perform effective heat radiation. In addition, the headlamp 6000 may further include a housing 6009 fixedly supporting the heat radiating unit 6012 and the reflective unit 6005. The housing 6009 may include a central hole 6008 formed in one surface 6006 thereof, through which the heating radiating unit 6012 is coupled and installed therein. In addition, the housing 6009 may include a front hole 6007 formed in another surface integrated with the one surface described above and bent in a direction orthogonal with respect to the one surface. Therefore, the front of the headlamp 6000 may be open due to the reflective unit 6005, and the reflective unit 6005 may be fixed to the housing 6009 such that the open front side corresponds to the front hole 6007, whereby light reflected through the reflective unit 6005 may be emitted to the outside through the front hole 6007.

As set forth above, according to an embodiment of the inventive concept, a light emitting device capable of having improved light emission efficiency by allowing electrons and holes to more effectively be injected into an active layer may be provided.

In addition, a method of effectively manufacturing such a light emitting device may be provided. The method may include forming a base layer configured of a group III nitride semiconductor, on a substrate. The method may also include forming a polarity modifying layer by oxidation or nitride processing at least an upper surface of the base layer. The method may further include forming a light emitting laminate including a first conductive semiconductor layer, an active layer and a second conductive semiconductor layer, on the polarity modifying layer. The forming of the polarity modifying layer may include forming an oxide film having one to ten atomic layers by oxidizing the upper surface of the base layer. The forming of the polarity modifying layer may be performed under an ozone gas atmosphere. The forming of the light emitting laminate may include forming an N polar surface on an upper surface of at least one of the first conductive semiconductor layer, the active layer and the second conductive semiconductor layer.

While the inventive concept has been shown and described in connection with the embodiments thereof, it will be apparent to those skilled in the art that modifications and variations can be made without departing from the spirit and scope of the inventive concept as defined by the appended claims.

What is claimed is:

1. A semiconductor light emitting device comprising:
a base layer comprising a group III nitride semiconductor;
a polarity modifying layer disposed on a group III element polar surface of the base layer; and
a light emitting laminate having a multilayer structure of the group III nitride semiconductor disposed on the polarity modifying layer, an upper surface of at least one layer in the multilayer structure being formed as an N polar surface.

2. The semiconductor light emitting device of claim 1, wherein the base layer comprises AlN.

3. The semiconductor light emitting device of claim 2, wherein an upper surface of the base layer comprises an Al polar surface.

4. The semiconductor light emitting device of claim 1, wherein the polarity modifying layer comprises an oxide obtained from a material of the base layer.

5. The semiconductor light emitting device of claim 4, wherein the polarity modifying layer comprises an Al oxide.

6. The semiconductor light emitting device of claim 1, wherein the polarity modifying layer comprises a nitride obtained from the material of the base layer.

7. The semiconductor light emitting device of claim 1, wherein the light emitting laminate includes a first conductive semiconductor layer, an active layer and a second conductive semiconductor layer, each layer comprising a group III nitride semiconductor.

8. The semiconductor light emitting device of claim 7, wherein the first conductive semiconductor layer, the active layer and the second conductive semiconductor layer are sequentially disposed on the polarity modifying layer.

9. The semiconductor light emitting device of claim 8, wherein in the light emitting laminate, at least an upper surface of the first conductive semiconductor layer comprises an N polar surface.

10. The semiconductor light emitting device of claim 8, wherein respective upper surfaces of the first conductive semiconductor layer, the active layer and the second conductive semiconductor layer comprise the N polar surface.

11. The semiconductor light emitting device of claim 1, wherein the base layer is formed on a substrate comprising a material different from that of the base layer.

12. The semiconductor light emitting device of claim 11, wherein the substrate comprises sapphire and a surface of the substrate directed toward the base layer is an Al polar surface.

13. The semiconductor light emitting device of claim 11, wherein the base layer comprises AlN, and the base layer and the substrate do not have a different base layer comprising GaN therebetween.

14. The semiconductor light emitting device of claim 1, wherein the base layer has a thickness of 20 to 200 nm.

15. The semiconductor light emitting device of claim 1, wherein the polarity modifying layer has a thickness of 0.3 to 10 nm.

16. A semiconductor light emitting device comprising:
a substrate;
a base layer disposed on the substrate, the base layer comprising AlN and having an Al polar upper surface;
a polarity modifying layer disposed on the Al polar upper surface and comprising Al oxide; and
a nitride semiconductor layer disposed on the polarity modifying layer and having an N polar upper surface.

17. A method of manufacturing a semiconductor light emitting device, comprising:
forming a base layer comprising a group III nitride semiconductor, on a substrate;
forming a polarity modifying layer by oxidation or nitride processing at least an upper surface of the base layer; and
forming a light emitting laminate comprising a first conductive semiconductor layer, an active layer and a second conductive semiconductor layer, on the polarity modifying layer.

18. The method of claim 17, wherein the forming of the polarity modifying layer comprises forming an oxide film having one to ten atomic layers by oxidizing the upper surface of the base layer.

19. The method of claim 18, wherein the forming of the polarity modifying layer is performed under an ozone gas atmosphere.

20. The method of claim 17, wherein the step of forming the light emitting laminate comprises forming an N polar surface on an upper surface of at least one of the first conductive semiconductor layer, the active layer and the second conductive semiconductor layer.
